(19) United States
(12) Patent Application Publication
(10) Pub. No.: US 2025/0126706 A1
(43) Pub. Date: Apr. 17, 2025

(54) NON-COPLANAR PARALLEL RESISTANCE-REDUCING CIRCUIT STRUCTURE

(71) Applicant: AAC Microtech (Changzhou) Co., Ltd., Changzhou (CN)

(72) Inventor: Guohui Chen, Changzhou (CN)

(21) Appl. No.: 18/536,277

(22) Filed: Dec. 12, 2023

Related U.S. Application Data
(63) Continuation of application No. PCT/CN2023/124335, filed on Oct. 12, 2023.

(51) Int. Cl. H05K 1/02

(52) U.S. Cl. CPC H05K 1/0298; H05K 2201/09545; H05K 2201/09672; H05K 2201/0979

(57) ABSTRACT

This application provides a non-coplanar parallel resistance-reducing circuit structure, including a first circuit layer, a first insulating layer stackedly fixed to the first circuit layer, a second circuit layer stackedly fixed to the first insulating layer, a first electroplated copper layer attached and fixed to a side of the first circuit layer away from the first insulating layer and a second electroplated copper layer stackedly fixed to a side of the second circuit layer away from the first insulating layer. The circuit structure further includes one or more via holes running through ends of the first circuit layer, the first insulating layer and the second circuit layer in sequence, and a wall of the via hole is copper-plated to enable parallel connection of the first circuit layer with the second circuit layer.

### CROSS-REFERENCE TO RELATED APPLICATIONS

This application is a continuation of International Patent Application No. PCT/CN2023/124335, filed on Oct. 12, 2023. The content of the aforementioned application, including any intervening amendments made thereto, is incorporated herein by reference in its entirety.

### TECHNICAL FIELD

The present application relates to electronic technology, and more particularly to a non-coplanar parallel resistance-reducing circuit structure.

### BACKGROUND

With the rapid development of electronic products, different electronic products have different resistance values, and in the circuit design, some electronic products have resistance limitation requirements. The resistance of the conductor in electronic products is mainly determined by the conductor thickness, length and width. Specifically, the conductor resistance R is directly proportional to its length L and resistivity ρ, and is inversely proportional to its cross-sectional area S, calculated by R=ρL/S, where ρ: the resistivity of the material for making the resistor; L: the length of the wire wound into the resistor; and S: the cross-sectional area of the wire wound into the resistor.

In the electronic products of the related technology, for reducing the circuit resistance, it is usually possible to reduce the conductor resistance by reducing the length of the circuit line, increasing the conductor thickness, and increasing the conductor line width. However, due to the limitation of structural space, it is impossible to increase the line width to meet the resistance-reduction requirements, and due to limitation of the thickness of the metal raw material, the effect of controlling the resistance reduction is poor.

Therefore, it is necessary to provide a novel non-coplanar parallel resistance-reducing circuit structure to solve the above technical problems.

### SUMMARY

An object of the present application is to provide a non-coplanar parallel resistance-reducing circuit structure, which can effectively control the circuit resistance and reduce the heat generation of an electronic product.

Technical solutions of this application will be specifically described below.

This application provides a non-coplanar parallel resistance-reducing circuit structure, comprising:
a first circuit layer;
a first insulating layer stackedly fixed to the first circuit layer;
a second circuit layer stackedly fixed to the first insulating layer;
a first electroplated copper layer attached and fixed to a side of the first circuit layer away from the first insulating layer; and
a second electroplated copper layer stackedly fixed to a side of the second circuit layer away from the first insulating layer;
wherein the non-coplanar parallel resistance-reducing circuit structure further comprises one or more via holes running through ends of the first circuit layer, the first insulating layer and the second circuit layer in sequence; and a wall of each of the one or more via holes is copper-plated to enable parallel connection of the first circuit layer with the second circuit layer.

In some embodiments, the non-coplanar parallel resistance-reducing circuit structure further comprises:
at least one line unit layer stackedly fixed to the second circuit layer in sequence;
wherein each of the at least one line unit layer comprises a second insulating layer and a third circuit layer adhering to each other; in each of the at least one line unit layer, the second insulating layer is closer to the second circuit layer in relation to the third circuit layer; and each of the one or more via holes runs through all of the at least one line unit layer.

In some embodiments, the first insulating layer and the second insulating layer are both made of an insulating material or an adhesive composite material.

In some embodiments, the first circuit layer, the second circuit layer and the third circuit layer are electrically connected in parallel through the one or more via holes.

In some embodiments, the non-coplanar parallel resistance-reducing circuit structure further comprises:
two pads or test points;
wherein the two pads or test points are arranged spaced apart at the first circuit layer.

In some embodiments, a line length of the first circuit layer is the same as a line length of the second circuit layer; the number of the one or more via holes is at least two; and the first circuit layer and the second circuit layer are connected in parallel through at least two via holes.

In some embodiments, a line length of the first circuit layer is different from a line length of the second circuit layer; the number of the one or more via holes is at least two; and the first circuit layer and the second circuit layer are connected in parallel through at least two via holes.

In some embodiments, the first circuit layer, the second circuit layer and the third circuit layer are the same in line length; the number of the one or more via holes is at least two; and the first circuit layer, the second circuit layer and the third circuit layer are connected in parallel through at least two via holes.

In some embodiments, the first circuit layer, the second circuit layer and the third circuit layer vary in line length; the number of the one or more via holes is at least two; and the first circuit layer, the second circuit layer and the third circuit layer are connected in parallel through at least two via holes.

In some embodiments, each of the one or more via holes is a round hole.

Compared to the prior art, this application has the following beneficial effects.

The non-coplanar parallel resistance-reducing circuit structure provided herein includes a first circuit layer, a first insulating layer stackedly fixed to the first circuit layer, a second circuit layer stackedly fixed to the first insulating layer, a first electroplated copper layer attached and fixed to the first circuit layer and a second electroplated copper layer stackedly fixed to the second circuit layer. The non-coplanar parallel resistance-reducing circuit structure further includes one or more via holes running through ends of the first circuit layer and the second circuit layer in sequence, and a wall of each via hole is copper-plated to enable parallel connection of the first circuit layer with the second circuit layer. The non-coplanar parallel resistance-reducing circuit structure can effectively control the circuit resistance and reduce the heat generation during operation, allowing for high safety. Moreover, this application breaks through the limitations of conventional two-dimensional planar parallel circuits.

### BRIEF DESCRIPTION OF THE DRAWINGS

In order to illustrate the technical solutions in embodiments of the present disclosure more clearly, the drawings needed in the description of embodiments will be briefly introduced below. Obviously, presented in the drawings are merely some embodiments of the present disclosure, which are not intended to limit the present disclosure. For those skilled in the art, other drawings can be obtained based on these drawings without making creative effort.

FIG. 1 is a first schematic diagram of an internal structure of a non-coplanar parallel resistance-reducing circuit structure according to an embodiment of this application.

FIG. 2 is a second schematic diagram of the internal structure of the non-coplanar parallel resistance-reducing circuit structure according to an embodiment of this application.

FIG. 3 is a third schematic diagram of the internal structure of the non-coplanar parallel resistance-reducing circuit structure according to an embodiment of this application.

FIG. 4 is a fourth schematic diagram of the internal structure of the non-coplanar parallel resistance-reducing circuit structure according to an embodiment of this application.

FIG. 5 schematically shows a structure of the non-coplanar parallel resistance-reducing circuit structure according to an embodiment of this application in integral parallel connection.

FIG. 6 schematically shows a structure of the non-coplanar parallel resistance-reducing circuit structure according to an embodiment of this application in local parallel connection.

### DETAILED DESCRIPTION OF THE EMBODIMENTS

The present application will be described clearly and completely below with reference to the accompanying drawings and embodiments to make objects, technical solutions, and advantages of the present application clearer and better understood. It should be understood that provided below are merely some embodiments of the present application, which are not intended to limit the present application. Other embodiments obtained by those skilled in the art based on the embodiments disclosed herein without making creative effort shall fall within the scope of the present application.

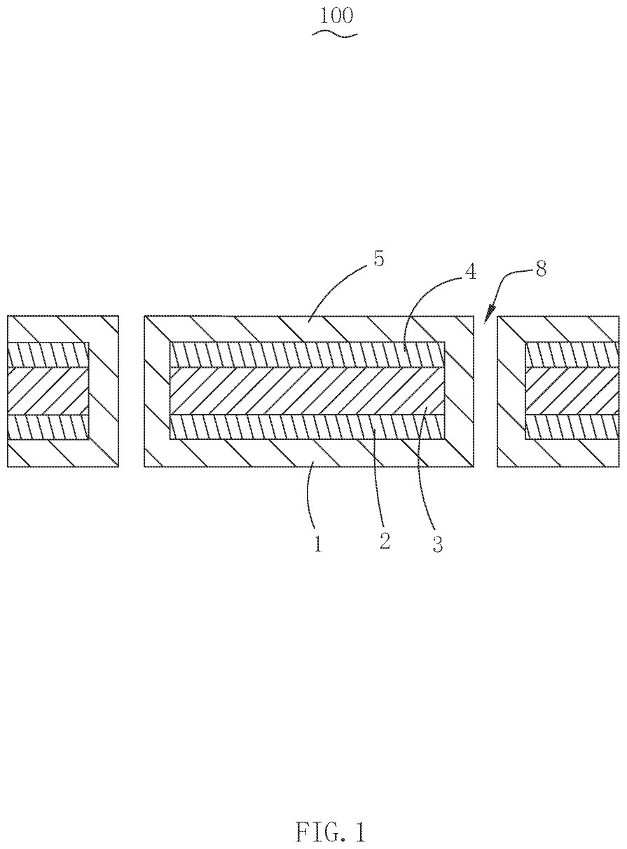

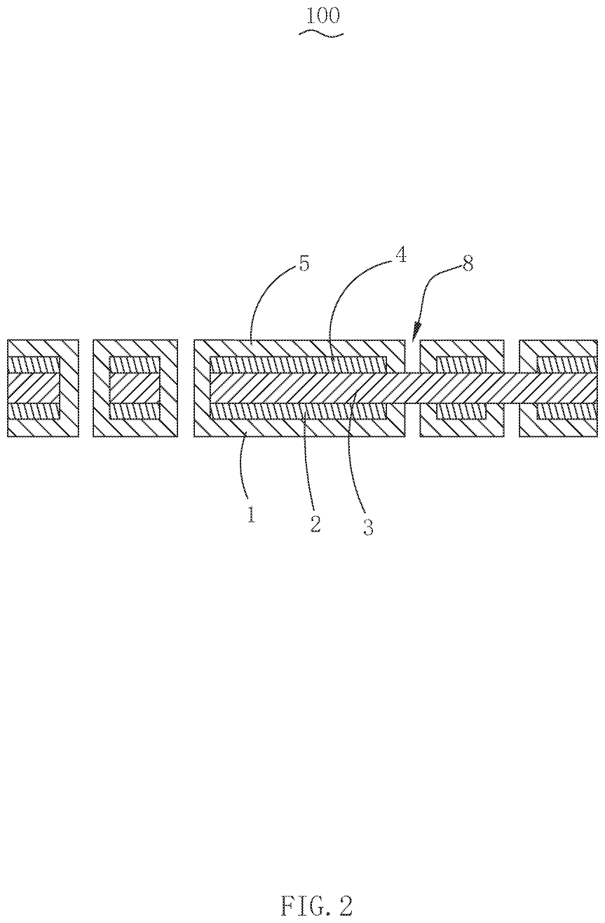

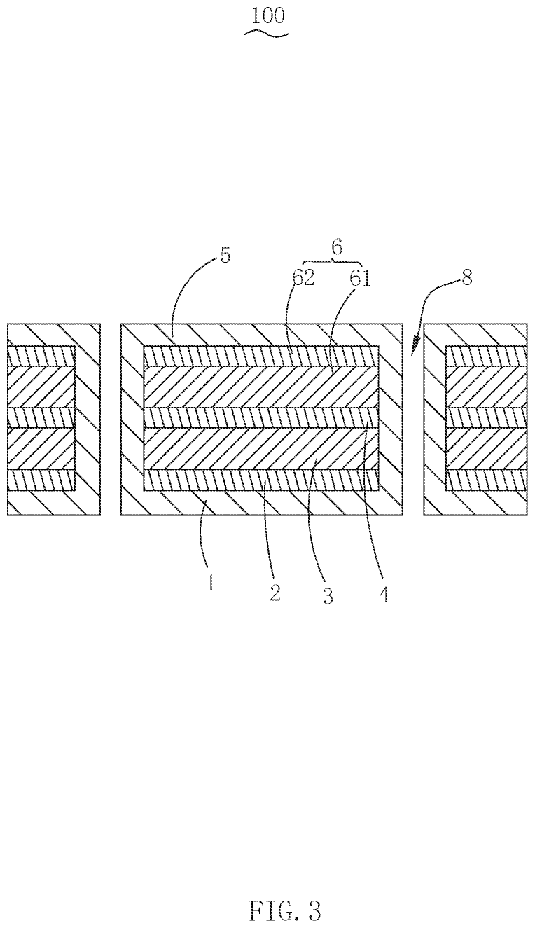

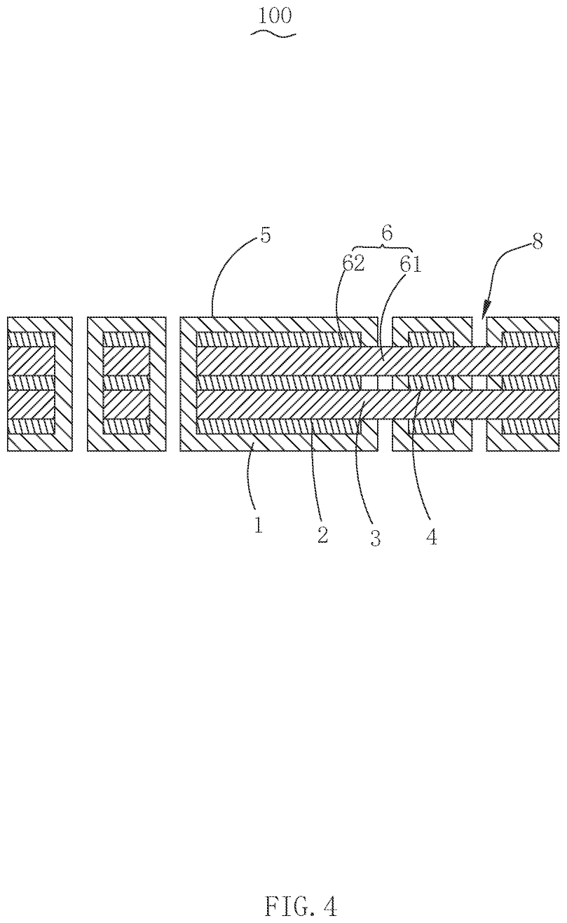

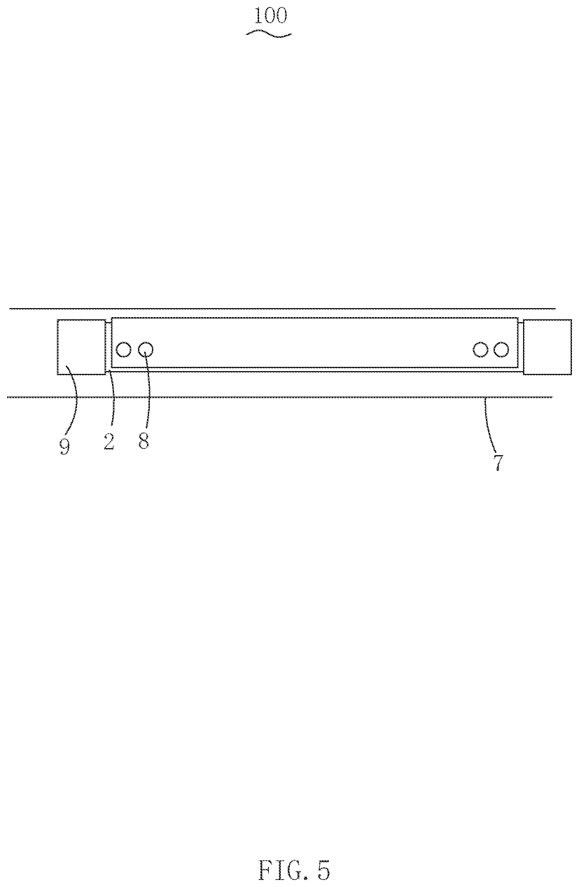

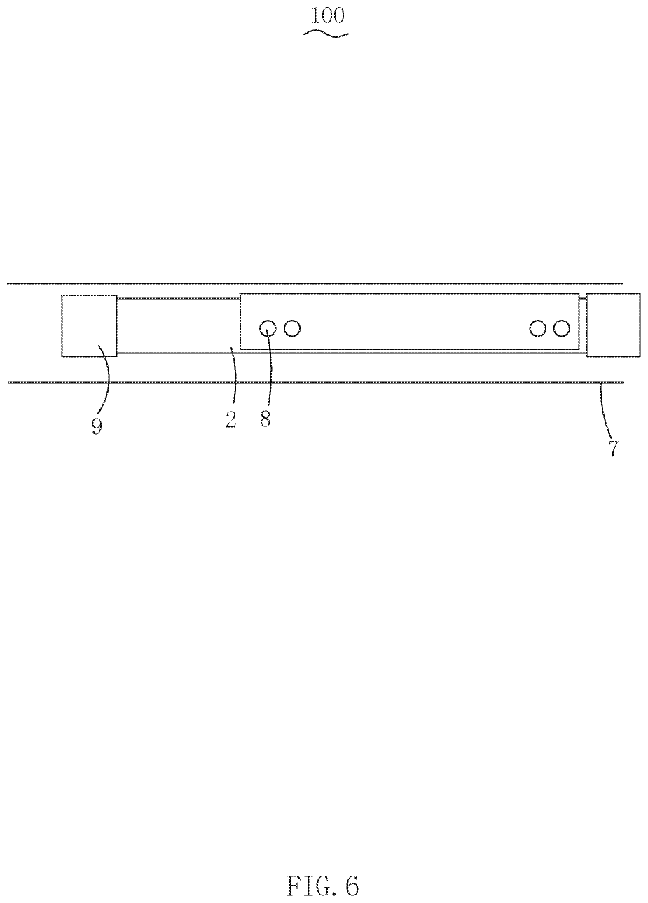

Referring to FIGS. 1-6, an embodiment of this application provides a non-coplanar parallel resistance-reducing circuit structure 100, which includes a first circuit layer 2, a first insulating layer 3 stackedly fixed to the first circuit layer 2, a second circuit layer 4 stackedly fixed to the first insulating layer 3, a first electroplated copper layer 1 attached and fixed to a side of the first circuit layer 2 away from the first insulating layer 3, and a second electroplated copper layer 5 stackedly fixed to a side of the second circuit layer 4 away from the first insulating layer 3. The first insulating layer 3 is configured to separate the first circuit layer 2 from the second circuit layer 4, so as to avoid the short circuit caused by direct lamination of the first circuit layer 2 and the second circuit layer 4. By electroplating the first electroplated copper layer 1 and the second electroplated copper layer 5 on the first circuit layer 2 and the second circuit layer 4, respectively, the first circuit layer 2 and the second circuit layer 4 can be effectively protected. Preferably, the first circuit layer 2 and the second circuit layer 4 are made of copper.

The non-coplanar parallel resistance-reducing circuit structure 100 further includes one or more via holes 8 running through ends of the first circuit layer 2, the first insulating layer 3 and the second circuit layer 4 in sequence, and a wall of each of the one or more via holes 8 is copper-plated to enable parallel connection of the first circuit layer 2 with the second circuit layer 4. The first circuit layer 2, the first electroplated copper layer 1, the second circuit layer 4 and the second electroplated copper layer 5 are used as a circuit forming carrier, and the first circuit layer 2 and the second circuit layer 4 are connected in parallel by copper plating of the walls of the via holes 8, which will effectively control the resistance value of the circuit, and reduce the heat generation of the circuit during operation. Multiple via holes 8 can be introduced in the parallel-connection area, and the more the via holes 8 are, the better the resistance reduction effect is. At the same time, it can also break through the limitations of the conventional two-dimensional planar parallel connection circuit, and has wide applicability.

In this embodiment, the non-coplanar parallel resistance-reducing circuit structure further includes at least one line unit layer 6 stackedly fixed to the second circuit layer 4 in sequence, and each line unit layer 6 includes a second insulating layer 61 and a third circuit layer 62 adhering to each other. In each line unit layer 6, the second insulating layer 61 is closer to the second circuit layer 4 in relation to the third circuit layer 62. Each of the one or more via holes 8 runs through all the line unit layer 6.

Specifically, the via holes 8 are configured to run through the first second electroplated copper layer 5, the third circuit layer 62, the second insulating layer 61, the second circuit layer 4, the first insulating layer 3, the first circuit layer 2 and the first electroplated copper layer 1 in sequence, such that two ends of the first circuit layer 2, the second circuit layer 4 and the third circuit layer 62 are connected in parallel through the via holes 8, so as to effectively control the resistance value of the circuit and avoid the excessive heat generation of the circuit during operation.

In an embodiment, the first insulating layer 3 and the second insulating layer 61 can be repeatedly stacked, and are not limited to the single-insulating layer structure. Of course, the first circuit layer 2, the second circuit layer 4 and the third circuit layer 62 may also be repeatedly stacked, and are not limited to the single-circuit layer structure. The parallel-connection design between the circuit layers can be adjusted by arranging different circuit layers.

In this embodiment, the first insulating layer 3 and the second insulating layer 61 are both made of an insulating material or an adhesive composite material, allowing for excellent insulation performance.

In this embodiment, the first circuit layer 2, the second circuit layer 4 and the third circuit layer 62 are electrically connected in parallel through the via holes 8.

In this embodiment, the non-coplanar parallel resistance-reducing circuit structure 100 further includes two pads 9 or test points, which are arranged spaced apart at the first circuit layer 2.

In this embodiment, the non-coplanar parallel resistance-reducing circuit structure 100 further includes a casing 7, which is configured to protect the internal circuit structure.

In this embodiment, a line length of the first circuit layer 2 is the same as a line length of the second circuit layer 4, and the first circuit layer 2 and the second circuit layer 4 are connected in parallel through at least two via holes 8.

The first circuit layer 2 and the second circuit layer 4 are stacked to form a non-coplanar structure. The line length consistence between the first circuit layer 2 and the second circuit layer 4 indicates that the line length of the first circuit layer 2 is the same as the line length of the second circuit layer 4.

In an embodiment, the first circuit layer 2, the second circuit layer 4 and the third circuit layer 62 are stacked to form a non-coplanar structure. The line length consistence between the first circuit layer 2, the second circuit layer 4 and the third circuit layer 62 indicates that the first circuit layer 2, the second circuit layer 4 and the third circuit layer 62 are the same in line length, that is, an orthographic projection of the third circuit layer 62 along the first circuit layer 2 can completely cover the second circuit layer 4 and the first circuit layer 2.

Specifically, a parallel region is formed between the pads 9 or test points at the ends of the first circuit layer 2, and non-coplanar circuits of the first circuit layer 2 and the second circuit layer 4 of the same length are connected in parallel through the via holes 8. The number of via holes 8 in the resistance-reducing parallel circuit formed by the parallel connection of the first circuit layer 2 and the second circuit layer 4 is greater than or equal to 2. More than 0 via holes 8 can be introduced to the parallel region, and the greater the number of via holes 8 is, the better the resistance-reducing effect is.

In an embodiment, the line length of the first circuit layer 2 is different from that of the second circuit layer 4, and the first circuit layer 2 and the second circuit layer 4 are connected in parallel through at least two via holes 8.

The inconsistency between the line length of the first circuit layer 2 and the second circuit layer 4 indicates that the line length of the first circuit layer 2 is non-coplanarly different from the line length of the second circuit layer 4.

More preferably, the inconsistency with the line length of the first circuit layer 2 indicates that the line length of the first circuit layer 2 is non-coplanarly different from the line length of the second circuit layer 4 and/or the line length of the third circuit layer 62.

Specifically, a parallel region is formed between the pads 9 or test points at the ends of the first circuit layer 2, and local non-coplanar circuits of the first circuit layer 2 and the second circuit layer 4 are connected in parallel through the via holes 8. The number of via holes 8 in the resistance-reducing parallel circuit formed by the parallel connection of the first circuit layer 2 and the second circuit layer 4 is greater than or equal to 2. More than 0 via holes 8 can be introduced to the parallel region, and the greater the number of via holes 8 is, the better the resistance-reducing effect is. Preferably, the number of the via holes 8 is four.

In this embodiment, each via hole 8 is a round hole.

In this embodiment, the first circuit layer 2 and the second circuit layer 4 are rectangular, which facilitates the stacking of multiple circuit layers.

Compared to the prior art, the non-coplanar parallel resistance-reducing circuit structure provided herein includes a first circuit layer, a first insulating layer stackedly fixed to the first circuit layer, a second circuit layer stackedly fixed to the first insulating layer, a first electroplated copper layer attached and fixed to the first circuit layer and a second electroplated copper layer stackedly fixed to the second circuit layer. The non-coplanar parallel resistance-reducing circuit structure further includes one or more via holes running through ends of the first circuit layer and the second circuit layer in sequence, and a wall of each via hole is copper-plated to enable parallel connection of the first circuit layer with the second circuit layer. The non-coplanar parallel resistance-reducing circuit structure can effectively control the circuit resistance and reduce the heat generation during operation, allowing for high safety. Moreover, this application breaks through the limitations of conventional two-dimensional planar parallel circuits.

Described above are only preferred embodiments of the present application, which are not intended to limit the present application. It should be noted that any variations, replacements and modifications made by those of ordinary skill in the art without departing from the spirit and scope of the present application shall fall within the scope of the present application defined by the appended claims.

What is claimed is:

1. A non-coplanar parallel resistance-reducing circuit structure, comprising:
a first circuit layer;
a first insulating layer stackedly fixed to the first circuit layer;
a second circuit layer stackedly fixed to the first insulating layer;
a first electroplated copper layer attached and fixed to a side of the first circuit layer away from the first insulating layer; and
a second electroplated copper layer stackedly fixed to a side of the second circuit layer away from the first insulating layer;
wherein the non-coplanar parallel resistance-reducing circuit structure further comprises one or more via holes running through ends of the first circuit layer, the first insulating layer and the second circuit layer in sequence; and a wall of each of the one or more via holes is copper-plated to enable parallel connection of the first circuit layer with the second circuit layer.

2. The non-coplanar parallel resistance-reducing circuit structure of claim 1, further comprising:
at least one line unit layer stackedly fixed to the second circuit layer in sequence;
wherein each of the at least one line unit layer comprises a second insulating layer and a third circuit layer adhering to each other; in each of the at least one line unit layer, the second insulating layer is closer to the second circuit layer in relation to the third circuit layer; and each of the one or more via holes runs through all of the at least one line unit layer.

3. The non-coplanar parallel resistance-reducing circuit structure of claim 2, wherein the first insulating layer and the second insulating layer are both made of an insulating material or an adhesive composite material.

4. The non-coplanar parallel resistance-reducing circuit structure of claim 2, wherein the first circuit layer, the second circuit layer and the third circuit layer are electrically connected in parallel through the one or more via holes.

5. The non-coplanar parallel resistance-reducing circuit structure of claim 1, further comprising:
two pads or test points;
wherein the two pads or test points are arranged spaced apart at the first circuit layer.

6. The non-coplanar parallel resistance-reducing circuit structure of claim 1, wherein a line length of the first circuit layer is the same as a line length of the second circuit layer; the number of the one or more via holes is at least two; and the first circuit layer and the second circuit layer are connected in parallel through at least two via holes.

7. The non-coplanar parallel resistance-reducing circuit structure of claim 1, wherein a line length of the first circuit layer is different from a line length of the second circuit layer; the number of the one or more via holes is at least two; and the first circuit layer and the second circuit layer are connected in parallel through at least two via holes.

8. The non-coplanar parallel resistance-reducing circuit structure of claim 2, wherein the first circuit layer, the second circuit layer and the third circuit layer are the same in line length; the number of the one or more via holes is at least two; and the first circuit layer, the second circuit layer and the third circuit layer are connected in parallel through at least two via holes.

9. The non-coplanar parallel resistance-reducing circuit structure of claim 2, wherein the first circuit layer, the second circuit layer and the third circuit layer vary in line length; the number of the one or more via holes is at least two; and the first circuit layer, the second circuit layer and the third circuit layer are connected in parallel through at least two via holes.

10. The non-coplanar parallel resistance-reducing circuit structure of claim 1, wherein each of the one or more via holes is a round hole.
